(19) United States
(12) Patent Application Publication
(10) Pub. No.: US 2025/0391682 A1
(43) Pub. Date: Dec. 25, 2025

(54) STATE PREDICTION DEVICE, STATE PREDICTION METHOD AND STATE PREDICTION SYSTEM

(71) Applicant: HITACHI HIGH-TECH CORPORATION, Minato-ku, Tokyo (JP)

(72) Inventors: Iqra Rehmat ALI, Tokyo (JP); Satoru MATSUKURA, Tokyo (JP); Yoshito KAMAJI, Tokyo (JP); Masahiro SUMIYA, Tokyo (JP)

(21) Appl. No.: 18/688,913

(22) PCT Filed: Mar. 17, 2023
(86) PCT No.: PCT/JP2023/010690

§ 371 Date: Mar. 4, 2024

(51) Int. Cl. H01L 21/67; G01R 31/26

(52) U.S. Cl. CPC H01L 21/67253; G01R 31/2607

(57) ABSTRACT

Aspects relate to generating a highly-accurate state prediction result for a semiconductor manufacturing device. A state prediction device for a semiconductor manufacturing device includes a data acquisition unit for acquiring a first set of operation data for a first processing chamber and a second set of operation data for a second processing chamber; a feature management unit for generating first and second feature maps; a correlation calculation unit for calculating a normalized cross-correlation result that indicates a uniformity level of a target feature between the first and second feature maps; a ranking unit for ranking target features based on the normalized cross-correlation result and selecting a subset of target features that achieve a ranking threshold; and a state prediction unit for generating a state prediction result that characterizes a performance difference of the second processing chamber with respect to the first processing chamber based on the subset of target features.

### TECHNICAL FIELD

The present disclosure relates to a state prediction device, state prediction method and state prediction system.

### BACKGROUND ART

In recent years, in the manufacturing industry, efforts to improve productivity by effectively utilizing data obtained from manufacturing devices are attracting attention.

As an example, in the field of semiconductor manufacturing, plasma processing devices may be equipped with a multitude of sensors for data acquisition. The data obtained from those sensors may be used for early detection of device abnormalities as well as productivity improvement.

When processing the time-series signal obtained by a sensor, features that represent individual measurable properties or characteristics of the signal are extracted and analyzed. For example, “plasma impedance” may be a feature extracted from the time-series signal for analysis.

In general, when performing analysis of a time-series signal to determine the operational state of a plasma processing device, for instance, extracting more features can facilitate the generation of a more reliable, accurate state prediction result. However, analyzing a greater number of features can lead to challenges including increased computer resources, longer processing time, and larger amounts of training data.

Conventionally, techniques for reducing the number of features used for state prediction have been considered.

As an example, US Patent Application 2020/0064820 (Patent Document 1) discloses “Provided is a state prediction apparatus that predicts a state of the plasma processing apparatus, a first set of features that indicates the state of the plasma processing apparatus is determined based on monitored data of the plasma processing apparatus in a normal state, a second set of features that indicates the state of the plasma processing apparatus is determined based on monitored data of the plasma processing apparatus, the features in the second set are calculated by using the features in the first set, a model that predicts the state of the plasma processing apparatus is generated by using a subset of the first set of features, which is composed of the same kind of features selected in descending order of the calculated features in the second set, and the state of the plasma processing apparatus is predicted by using the generated model.”

### CITATION LIST

### Patent Literature

### [PTL 1]

US Patent Application 2020/0064820

### SUMMARY OF INVENTION

### Technical Problem

PTL 1 proposes a technique for predicting the state of a plasma processing device using a subset of the features of a signal obtained from the plasma processing device. The subset of features may be ranked in order of a standardized value that indicates the degree of deviation of the testing data from a normal device state.

However, while the technique of PTL 1 performs device state prediction based on standardized values that indicate the degree of deviation of the testing data from a normal device state, it does not consider the uniformity of features between data corresponding to acceptable chamber states and unacceptable chamber states. By selecting features in consideration of their uniformity between acceptable chamber states and unacceptable chamber states, it is possible to acquire a more accurate state prediction result.

Accordingly, aspects of the present disclosure relate to a state prediction technique that is capable of generating a highly-accurate state prediction result for a semiconductor manufacturing device based on features that are determined to have a high uniformity between acceptable chamber states and unacceptable chamber states.

One representative example of the present disclosure relates to a state prediction device including a data acquisition unit configured to acquire a first set of operation data for a first semiconductor manufacturing device that achieves an operational threshold, and acquire a second set of operation data for a second semiconductor manufacturing device that fails to achieve the operational threshold; a feature management unit configured to generate, based on the first set of operation data, a first feature map for a first target feature, and generate, based on the second set of operation data, a second feature map for the first target feature; a correlation calculation unit configured to calculate a normalized cross-correlation result that indicates a uniformity level of the first target feature between the first feature map and the second feature map; a ranking unit configured to assign, based on the normalized cross-correlation result, a ranking to the first target feature that indicates a relevance of the first target feature with respect to a set of target features with regard to semiconductor manufacturing device state prediction, and select, from among the set of target features, a subset of target features that achieve a ranking threshold; and a state prediction unit configured to generate, based on the subset of target features, a state prediction result that characterizes an operational state of the second semiconductor manufacturing device.

### Advantageous Effects of Invention

According to the present disclosure it is possible to provide a state prediction technique that is capable of generating a highly-accurate state prediction result for a semiconductor manufacturing device based on features that are determined to have a high uniformity between acceptable chamber states and unacceptable chamber states.

Problems, configurations, and effects other than those described above will be made clear by the following description in the embodiments for carrying out the invention.

### BRIEF DESCRIPTION OF DRAWINGS

FIG. 1 illustrates an example computing architecture for executing the embodiments of the present disclosure.

FIG. 2 is a diagram illustrating the functional configuration of the state prediction system according to the embodiments of the present disclosure.

FIG. 3 is a flowchart illustrating the flow of the state prediction result generation process according to the embodiments of the present disclosure.

FIG. 4 is a diagram illustrating the flow of the normalized cross-correlation result generation process according to the embodiments of the present disclosure.

FIG. 5 illustrates an example of a normalized cross-correlation result according to the embodiments of the present disclosure.

FIG. 6 is a diagram illustrating an example of a cross-correlation graph generated with respect to a set of feature maps corresponding to a target feature of plasma impedance, according to the embodiments of the present disclosure.

FIG. 7 is a diagram illustrating an example of a cross-correlation graph generated with respect to a set of feature maps corresponding to a target feature of magnetron current, according to the embodiments of the present disclosure.

FIG. 8 is a flowchart that illustrates an example flow of the target feature ranking process according to the embodiments of the present disclosure.

FIG. 9 is a flowchart illustrating an example flow of the state prediction result generation process according to the embodiments of the present disclosure.

FIG. 10 is a diagram illustrating an example of a time-series data signal of each sensor value acquired from a semiconductor manufacturing device according to the embodiments of the present disclosure.

FIG. 11 is a diagram illustrating an example of feature map data according to the embodiments of the present disclosure.

FIG. 12 illustrates an example of a set of feature values stored in a feature map, according to the embodiments of the present disclosure.

FIG. 13 is a diagram illustrating an example of the feature submap extraction according to the embodiments of the present disclosure.

FIG. 14 is a diagram illustrating an example of a template matching result according to the embodiments of the present disclosure.

### DESCRIPTION OF EMBODIMENT(S)

Herein, embodiments of the present invention will be described with reference to the Figures. It should be noted that the embodiments described herein are not intended to limit the invention according to the claims, and it is to be understood that each of the elements and combinations thereof described with respect to the embodiments are not strictly necessary to implement the aspects of the present invention.

Various aspects are disclosed in the following description and related drawings. Alternate aspects may be devised without departing from the scope of the disclosure. Additionally, well-known elements of the disclosure will not be described in detail or will be omitted so as not to obscure the relevant details of the disclosure.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

Further, many aspects are described in terms of sequences of actions to be performed by, for example, elements of a computing device. It will be recognized that various actions described herein can be performed by specific circuits (e.g., an application specific integrated circuit (ASIC)), by program instructions being executed by one or more processors, or by a combination of both. Additionally, the sequence of actions described herein can be considered to be embodied entirely within any form of computer readable storage medium having stored therein a corresponding set of computer instructions that upon execution would cause an associated processor to perform the functionality described herein. Thus, the various aspects of the disclosure may be embodied in a number of different forms, all of which have been contemplated to be within the scope of the claimed subject matter.

Hereinafter, a detailed description of the embodiments of the present disclosure will be described with reference to the Figures.

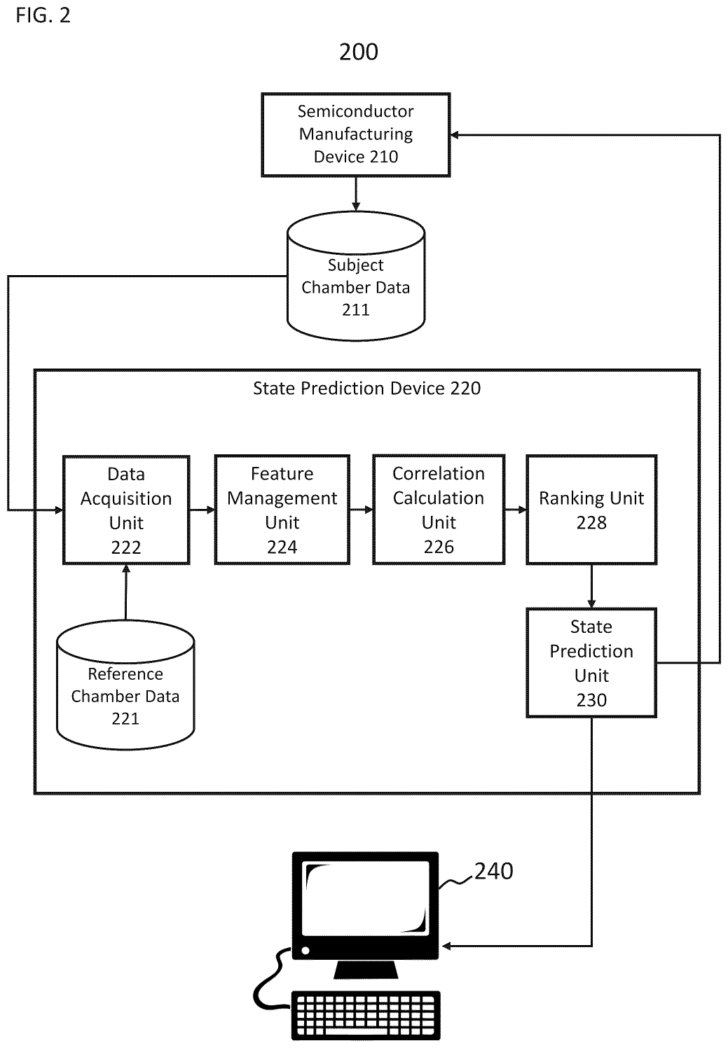

In general, the performance of semiconductor manufacturing devices (such as plasma processing devices) may change due to aging, component replacement, cleaning, or other factors. Such performance changes may manifest in the performance of the semiconductor devices manufactured by these semiconductor manufacturing devices. Accordingly, the state prediction system (for example, the state prediction system 200 illustrated in FIG. 2) according to the embodiments of the present disclosure is configured to identify and correct performance differences between processing chambers (hereinafter also referred to as chambers) of one or more semiconductor manufacturing devices. This performance difference may arise in a single chamber due to time elapse, component replacement or component cleaning of the chamber, or between different chambers (e.g., different chambers in different semiconductor manufacturing devices or the like).

Here, the “performance difference” between chambers refers to a difference in the processing results (e.g., a difference in etching amount, a difference in the thickness of the film formed) between plasma processing (e.g., etching, film formation) performed using a reference chamber and processing using a subject chamber. This performance difference between the plasma processing using the plasma generated in the reference chamber and the plasma processing using the plasma generated in the subject chamber can be quantified by comparing a semiconductor device manufactured by the semiconductor manufacturing device that includes the reference chamber and a semiconductor device manufactured by the semiconductor manufacturing device that includes the subject chamber. That is, the difference in performance between the plasma processing using plasma generated in the reference chamber and the plasma processing using plasma generated in the subject chamber manifests in the performance variation of the manufactured semiconductor devices.

A performance difference due to time elapse refers to a difference between the processing results of processing performed in a particular chamber at a first point in time and the processing results of processing performed in the same chamber at a second point in time later than the first point in time.

A performance difference due to component replacement or component cleaning refers to a difference between the processing results of processing performed in a particular chamber prior to component replacement or cleaning and the processing results of processing performed in the same chamber after replacement or cleaning.

The state prediction device, system, and method according to the present disclosure relate to a technique for generating a state prediction result that characterizes a performance difference of a subject processing chamber (e.g., a second processing chamber) with respect to a reference processing chamber (e.g., a first processing chamber), and using this state prediction result to adjust operational parameters of the subject processing chamber to reduce the performance difference of the subject processing chamber with respect to the reference processing chamber. As will be described herein, this state prediction result may be generated based on features that have a high uniformity between acceptable chamber states and unacceptable chamber states. Here, an “acceptable chamber state” refers to a processing chamber that achieves a predetermined performance level, whereas an “unacceptable chamber state” refers to a processing chamber that fails to achieve the predetermined performance level.

In this way, by generating the state prediction result using features that have a high uniformity between acceptable chamber states and unacceptable chamber states, it is possible to bring the subject processing chamber into alignment with (e.g., achieve a similar performance result as) the reference processing chamber.

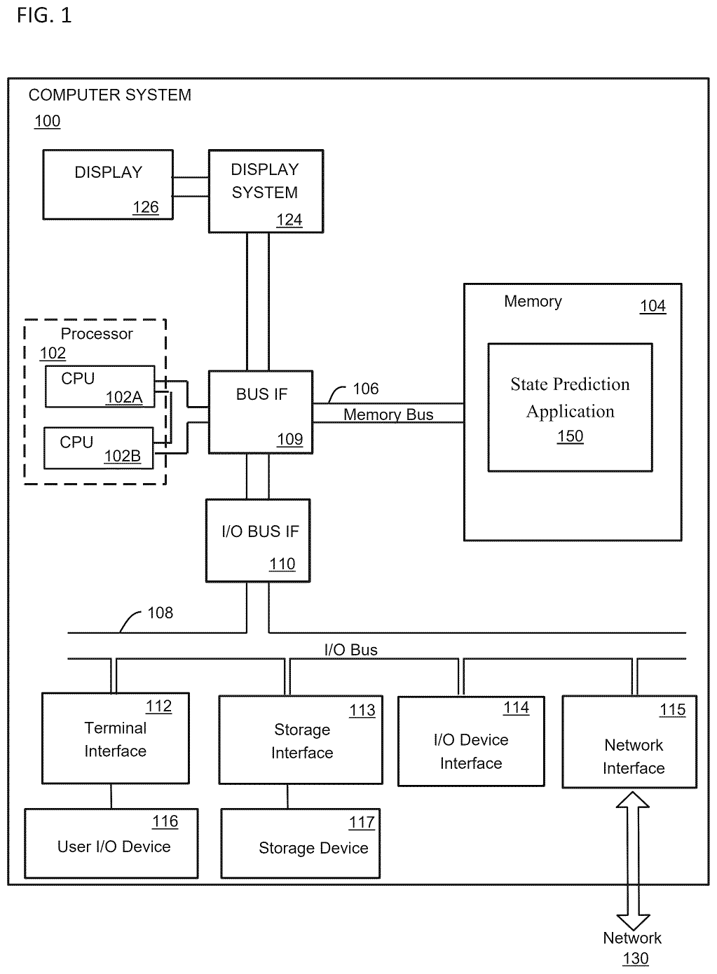

Turning now to the Figures, FIG. 1 depicts a high-level block diagram of a computer system 100 for implementing various embodiments of the present disclosure, according to embodiments. The mechanisms and apparatus of the various embodiments disclosed herein apply equally to any appropriate computing system. The major components of the computer system 100 include one or more processors 102, a memory 104, a terminal interface 112, a storage interface 113, an I/O (Input/Output) device interface 114, and a network interface 115, all of which are communicatively coupled, directly or indirectly, for inter-component communication via a memory bus 106, an I/O bus 108, bus interface unit 109, and an I/O bus interface unit 110.

The computer system 100 may contain one or more general-purpose programmable central processing units (CPUs) 102A and 102B, herein generically referred to as the processor 102. In embodiments, the computer system 100 may contain multiple processors; however, in certain embodiments, the computer system 100 may alternatively be a single CPU system. Each processor 102 executes instructions stored in the memory 104 and may include one or more levels of on-board cache.

In embodiments, the memory 104 may include a random-access semiconductor memory, storage device, or storage medium (either volatile or non-volatile) for storing or encoding data and programs. In certain embodiments, the memory 104 represents the entire virtual memory of the computer system 100, and may also include the virtual memory of other computer systems coupled to the computer system 100 or connected via a network. The memory 104 can be conceptually viewed as a single monolithic entity, but in other embodiments the memory 104 is a more complex arrangement, such as a hierarchy of caches and other memory devices. For example, memory may exist in multiple levels of caches, and these caches may be further divided by function, so that one cache holds instructions while another holds non-instruction data, which is used by the processor or processors. Memory may be further distributed and associated with different CPUs or sets of CPUs, as is known in any of various so-called non-uniform memory access (NUMA) computer architectures.

The memory 104 may store all or a portion of the various programs, modules and data structures for processing data transfers as discussed herein. For instance, the memory 104 can store a state prediction application 150. In embodiments, the state prediction application 150 may include instructions or statements that execute on the processor 102 or instructions or statements that are interpreted by instructions or statements that execute on the processor 102 to carry out the functions as further described below. In certain embodiments, the state prediction application 150 is implemented in hardware via semiconductor devices, chips, logical gates, circuits, circuit cards, and/or other physical hardware devices in lieu of, or in addition to, a processor-based system. In embodiments, the state prediction application 150 may include data in addition to instructions or statements. In certain embodiments, a camera, sensor, or other data input device (not shown) may be provided in direct communication with the bus interface unit 109, the processor 102, or other hardware of the computer system 100. In such a configuration, the need for the processor 102 to access the memory 104 and the state prediction application 150 may be reduced.

The computer system 100 may include a bus interface unit 109 to handle communications among the processor 102, the memory 104, a display system 124, and the I/O bus interface unit 110. The I/O bus interface unit 110 may be coupled with the I/O bus 108 for transferring data to and from the various I/O units. The I/O bus interface unit 110 communicates with multiple I/O interface units 112, 113, 114, and 115, which are also known as I/O processors (IOPs) or I/O adapters (IOAs), through the I/O bus 108. The display system 124 may include a display controller, a display memory, or both. The display controller may provide video, audio, or both types of data to a display device 126. Further, the computer system 100 may include one or more sensors or other devices configured to collect and provide data to the processor 102.

As examples, the computer system 100 may include biometric sensors (e.g., to collect heart rate data, stress level data), environmental sensors (e.g., to collect humidity data, temperature data, pressure data), motion sensors (e.g., to collect acceleration data, movement data), or the like. Other types of sensors are also possible. The display memory may be a dedicated memory for buffering video data. The display system 124 may be coupled with a display device 126, such as a standalone display screen, computer monitor, television, or a tablet or handheld device display.

In one embodiment, the display device 126 may include one or more speakers for rendering audio. Alternatively, one or more speakers for rendering audio may be coupled with an I/O interface unit. In alternate embodiments, one or more of the functions provided by the display system 124 may be on board an integrated circuit that also includes the processor 102. In addition, one or more of the functions provided by the bus interface unit 109 may be on board an integrated circuit that also includes the processor 102.

The I/O interface units support communication with a variety of storage and I/O devices. For example, the terminal interface unit 112 supports the attachment of one or more user I/O devices 116, which may include user output devices (such as a video display device, speaker, and/or television set) and user input devices (such as a keyboard, mouse, keypad, touchpad, trackball, buttons, light pen, or other pointing device). A user may manipulate the user input devices using a user interface in order to provide input data and commands to the user I/O device 116 and the computer system 100, and may receive output data via the user output devices. For example, a user interface may be presented via the user I/O device 116, such as displayed on a display device, played via a speaker, or printed via a printer.

The storage interface 113 supports the attachment of one or more disk drives or direct access storage devices 117 (which are typically rotating magnetic disk drive storage devices, although they could alternatively be other storage devices, including arrays of disk drives configured to appear as a single large storage device to a host computer, or solid-state drives, such as flash memory). In some embodiments, the storage device 117 may be implemented via any type of secondary storage device. The contents of the memory 104, or any portion thereof, may be stored to and retrieved from the storage device 117 as needed. The I/O device interface 114 provides an interface to any of various other I/O devices or devices of other types, such as printers or fax machines. The network interface 115 provides one or more communication paths from the computer system 100 to other digital devices and computer systems; these communication paths may include, for example, one or more networks 130.

Although the computer system 100 shown in FIG. 1 illustrates a particular bus structure providing a direct communication path among the processors 102, the memory 104, the bus interface 109, the display system 124, and the I/O bus interface unit 110, in alternative embodiments the computer system 100 may include different buses or communication paths, which may be arranged in any of various forms, such as point-to-point links in hierarchical, star or web configurations, multiple hierarchical buses, parallel and redundant paths, or any other appropriate type of configuration. Furthermore, while the I/O bus interface unit 110 and the I/O bus 108 are shown as single respective units, the computer system 100 may, in fact, contain multiple I/O bus interface units 110 and/or multiple I/O buses 108. While multiple I/O interface units are shown which separate the I/O bus 108 from various communications paths running to the various I/O devices, in other embodiments, some or all of the I/O devices are connected directly to one or more system I/O buses.

In various embodiments, the computer system 100 is a multi-user mainframe computer system, a single-user system, or a server computer or similar device that has little or no direct user interface, but receives requests from other computer systems (clients). In other embodiments, the computer system 100 may be implemented as a desktop computer, portable computer, laptop or notebook computer, tablet computer, pocket computer, telephone, smart phone, or any other suitable type of electronic device.

Next, with reference to FIG. 2, the state prediction system according to the embodiments of the present disclosure will be described.

FIG. 2 is a diagram illustrating the functional configuration of the state prediction system 200 according to the embodiments of the present disclosure. As illustrated in FIG. 2, the state prediction system 200 primarily includes a semiconductor manufacturing device 210, a state prediction device 220, and a user terminal 240. The semiconductor manufacturing device 210, the state prediction device 220, and the user terminal 240 may be communicatively connected via a communication network such as a local area network (LAN), the Internet, a wide area network (WAN), or the like.

The semiconductor manufacturing device 210 is a device used for manufacturing semiconductor devices. As an example, the semiconductor manufacturing device 210 may be a plasma processing apparatus that includes a processing chamber in which plasma processing is performed with respect to semiconductor substrates. For example, the semiconductor manufacturing device 210 may be a plasma etching device. The plasma processing conducted by the semiconductor manufacturing device 210 may be controlled by adjusting a set of operational parameters (e.g., coil current, microwave intensity, pressure, high-frequency bias power, plasma impedance). The processing chamber of the semiconductor manufacturing device 210 may be equipped with a plurality of sensors configured to monitor and measure the conditions of the processing chamber during plasma processing and transmit a set of subject chamber data 211 collected by the sensors to the state prediction device 220.

It should be noted that, for convenience of description, an example configuration of a state prediction system 200 including a single semiconductor manufacturing device 210 is illustrated in FIG. 2, but the state prediction system 200 according to the embodiments of the present disclosure is not limited herein, and configurations in which multiple semiconductor manufacturing devices are included are also possible.

The state prediction device 220 is a device configured to generate a state prediction result that characterizes a performance difference of a subject processing chamber (e.g., a second processing chamber) with respect to a reference processing chamber (e.g., a first processing chamber), and using this state prediction result to adjust operational parameters of the subject processing chamber to reduce the performance difference of with respect to the reference processing chamber. Here, the subject processing chamber and the reference processing chamber may be the same processing chamber in the semiconductor manufacturing device 210 at different times (e.g., before and after cleaning or component replacement), or may be different processing chambers in different semiconductor manufacturing devices (e.g., the semiconductor manufacturing device 210 and another semiconductor manufacturing device not illustrated in FIG. 2).

As illustrated in FIG. 2, the state prediction device 220 includes a set of reference chamber data 221, a data acquisition unit 222, a feature management unit 224, a correlation calculation unit 226, a ranking unit 228 and a state prediction unit 230. In embodiments, the state prediction device 220 may be implemented using the computer system 100 illustrated in FIG. 1, such that the set of reference chamber data 221 is stored within the storage device 117 of the computer system 100 and the functions of the data acquisition unit 222, the feature management unit 224, the correlation calculation unit 226, the ranking unit 228 and the state prediction unit 230 are implemented using software modules of the state prediction application 150 stored in the memory 104 of the computer system 100. Alternatively, the functions of the data acquisition unit 222, the feature management unit 224, the correlation calculation unit 226, the ranking unit 228 and the state prediction unit 230 may be implemented using dedicated hardware or integrated circuits.

The data acquisition unit 222 is a functional unit configured to acquire sets of chamber data that characterize the operating conditions within the processing chamber of a semiconductor manufacturing device. For example, the data acquisition unit 222 may acquire the set of subject chamber data 211 (e.g., a first set of operation data) collected by and transmitted from the semiconductor manufacturing device 210 as well as a set of reference chamber data (e.g., a second set of operation data) 221. As described herein, the set of subject chamber data 211 may be set of data that characterizes the operating conditions of a subject processing chamber during plasma processing that fails to achieve a performance threshold (e.g., an unacceptable chamber state), and may be acquired from the semiconductor manufacturing device 210. The set of reference chamber data 221 may be a set of data that characterizes the operating conditions of a reference processing chamber during plasma processing that achieves a performance threshold (e.g., an acceptable chamber state), and may be collected in advance and stored in the state prediction device 220.

As the functions of the data acquisition unit 222 will be described later, a detailed description thereof will be omitted here.

The feature management unit 224 is a functional unit configured to generate feature maps based on the chamber data acquired by the data acquisition unit 222. For instance, the feature management unit 224 may generate, based on the set of reference chamber data 221, a first feature map for a first target feature, and generate, based on the subject chamber data 211, a second feature map for the first target feature. Here, “target features” refer to individual measurable properties or characteristics of chamber data that correspond to adjustable operational parameters of a semiconductor manufacturing device processing chamber. Accordingly, “target features” may be considered to be data corresponding to operational parameters such as coil current, microwave intensity, pressure, high-frequency bias power, or any other operational parameter of the semiconductor manufacturing device 210.

As the functions of the feature management unit 224 will be described later, a detailed description thereof will be omitted here.

The correlation calculation unit 226 is a functional unit configured to calculate a normalized cross-correlation result between the feature maps generated by the feature management unit 224 for a particular target feature. For example, the correlation calculation unit 226 may calculate a normalized cross-correlation result that indicates a uniformity level of a first target feature between the first feature map and the second feature map.

As the functions of the correlation calculation unit 226 will be described later, a detailed description thereof will be omitted here.

The ranking unit 228 is a functional unit configured to rank the features of the feature maps generated by the feature management unit 224 based on the normalized cross-correlation result generated by the correlation calculation unit 226. For example, the ranking unit 228 may assign, based on the normalized cross-correlation result, a ranking to a first target feature that indicates a relevance of the first target feature with respect to a set of target features with regard to processing chamber state prediction, and select, from among the set of target features, a subset of target features that achieve a ranking threshold.

As the functions of the ranking unit 228 will be described later, a detailed description thereof will be omitted here.

The state prediction unit 230 is a functional unit for generating a state prediction result that characterizes a performance difference of the subject processing chamber with respect to the reference processing chamber. In embodiments, the state prediction result may indicate changes to a set of operation parameters of the semiconductor manufacturing device that includes the subject chamber (e.g., the semiconductor manufacturing device 210) to reduce the performance difference of the subject processing chamber with respect to the reference processing chamber. The state prediction result may be transmitted to the user terminal 240 for presentation to a user and also to the semiconductor manufacturing device 210 to facilitate adjustment of the operational parameters thereof.

As the functions of the state prediction unit 230 will be described later, a detailed description thereof will be omitted here.

The user terminal 240 is a device used by a user of the state prediction system 200. The user terminal 240 may be used to confirm the state prediction result generated by the state prediction unit 230, input data to the state prediction device 220, or the like via a graphical user interface. As examples, the user terminal 240 may include a laptop computer, desktop computer, smartphone, tablet, or other suitable computing device.

According to the state prediction system 200 described with reference to FIG. 2, it is possible to rank a set of target features present in feature maps corresponding to semiconductor manufacturing device chamber data based on the uniformity of a given target feature between acceptable chamber states and unacceptable chamber states, and subsequently use highly-ranked target features to generate a state prediction result that characterizes the performance difference of the subject processing chamber with respect to the reference processing chamber. This state prediction result can then be used to adjust operating parameters of the semiconductor manufacturing device including the subject processing chamber to reduce the performance difference between the subject processing chamber and the reference processing chamber.

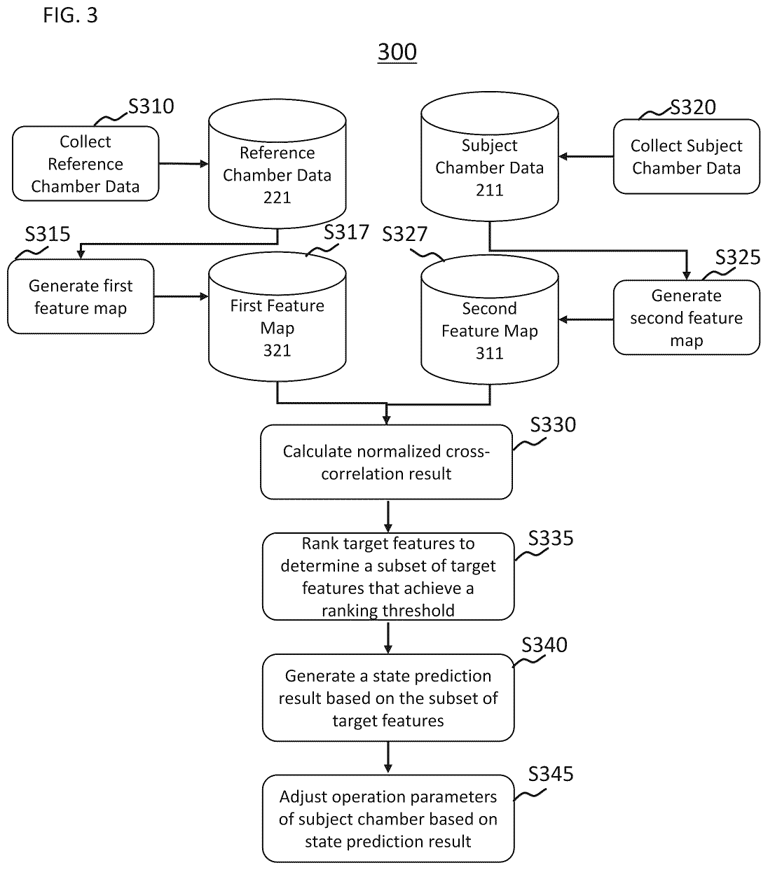

Next, with reference to FIG. 3, an overview of the state prediction result generation process according to the embodiments of the present disclosure will be described.

FIG. 3 is a flowchart illustrating the flow of the state prediction result generation process 300 according to the embodiments of the present disclosure. The state prediction result generation process 300 is a process for generating a highly-accurate state prediction result for a semiconductor manufacturing device based on features that are determined to have a high uniformity between acceptable chamber states and unacceptable chamber states. The state prediction result generation process 300 may be performed by the functional units of the state prediction device 220 illustrated in FIG. 2.

First, at Step S310, the data acquisition unit 222 acquires the reference chamber data 221. In embodiments, in a reference chamber in a semiconductor manufacturing device, plasma may be generated while a plurality of operational parameter setting values are varied at specific intervals in a specific value range, plasma processing may be performed with respect to a semiconductor substrate, and data characterizing the conditions of the reference chamber during plasma processing may be collected using the various sensors mounted in the semiconductor manufacturing device and acquired by the data acquisition unit 222 as reference chamber data 221. The collected reference chamber data 221 may be a time-series signal that characterizes the conditions of the reference chamber during plasma processing.

Here, the reference chamber may be a plasma processing chamber that achieves a performance threshold (e.g., produces plasma processing results that achieve a desired quality standard). Herein, a processing chamber that achieves a performance threshold may also be referred to as a chamber that has an “acceptable chamber state.”

Next, at Step S315, the feature management unit 224 generates a feature map for the reference chamber data 221. More particularly, the feature management unit 224 may use the reference chamber data 221 to calculate representative values of the sensor values collected during plasma processing at the operational parameter setting values varied in Step S310. That is, the feature management unit 224 may perform one or more arithmetic operations on the operational parameter values in the reference chamber data 221 to calculate a plurality of representative values of plasma generation characteristics under a variety of processing conditions.

Subsequently, the feature management unit 224 may perform arithmetic operations on the calculated representative values to calculate feature values for a set of target features (e.g., features corresponding to adjustable operational parameters of the plasma processing chamber such as coil-voltage, magnetron current, valve opening degree and the like), and map these feature values onto a two-dimensional or more graph having axes that correspond to particular target features to generate the first feature map 321.

In this way, the feature management unit 224 can generate a first feature map 321 that contains feature values for target features that represent operational parameters characterized by the reference chamber data 221. As will be described later, this first feature map 321 can be used as a reference feature map to ascertain the performance difference of a subject chamber with respect to the reference chamber.

Here, for convenience of explanation, reference will be made to a first feature map corresponding to a first target feature of the reference chamber data 221, but in practice, feature maps for a plurality of target features characterizing the reference chamber data may be generated and processed according to the following steps.

At Step S320, the data acquisition unit 222 acquires the subject chamber data 211. In embodiments, in a subject chamber in a semiconductor manufacturing device, plasma may be generated while a plurality of operational parameter setting values are varied at specific intervals in a specific value range, plasma processing may be performed with respect to a semiconductor substrate, and data characterizing the conditions of the subject chamber during plasma processing may be collected using the various sensors mounted in the semiconductor manufacturing device and acquired by the data acquisition unit 222 as subject chamber data 211. The collected subject chamber data 211 may be a time-series signal that characterizes the conditions of the subject chamber during plasma processing.

Here, the subject chamber may be a plasma processing chamber that fails to achieve a performance threshold (e.g., produces plasma processing results that do not achieve a desired quality standard). Herein, a processing chamber that fails to achieve a performance threshold may also be referred to as a chamber that has an “unacceptable chamber state.”

Next, at Step S325, the feature management unit 224 generates a feature map for the subject chamber data 211. More particularly, the feature management unit 224 may use the subject chamber data 211 to calculate representative values of the sensor values collected during plasma processing at the operational parameter setting values varied in Step S320. That is, the feature management unit 224 may perform one or more arithmetic operations on the operational parameter values in the subject chamber data 211 to calculate a plurality of representative values of plasma generation characteristics under a variety of processing conditions.

Subsequently, the feature management unit 224 may perform arithmetic operations on the calculated representative values to calculate feature amounts, and map these feature amounts onto a two-dimensional or more graph having axes that correspond to particular target features (e.g., features corresponding to adjustable operational parameters of the plasma processing chamber such as coil-voltage, magnetron current, valve opening degree and the like) to generate the second feature map 311.

In this way, the feature management unit 224 can generate a second feature map 311 that contains feature values for target features that represent operational parameters characterized by the subject chamber data 211. As will be described later, this second feature map 311 can be compared with the first feature map 321 to ascertain the performance difference of the subject chamber with respect to the reference chamber. Here, for convenience of explanation, reference will be made to a second feature map corresponding to a first target feature (e.g., the same target feature as that of the first feature map 321) of the subject chamber data 211, but in practice, feature maps for a plurality of target features characterizing the subject chamber data may be generated and processed according to the following steps.

Next, at Step S330, the correlation calculation unit 226 calculates a normalized cross-correlation result that indicates a uniformity level of the first target feature between the first feature map 321 and the second feature map 311. Here, the uniformity level refers to the degree of similarity of the first target feature between the first feature map and the second feature map. Using this normalized cross-correlation result, it is possible to identify those target features that best represent the conditions of the processing chambers.

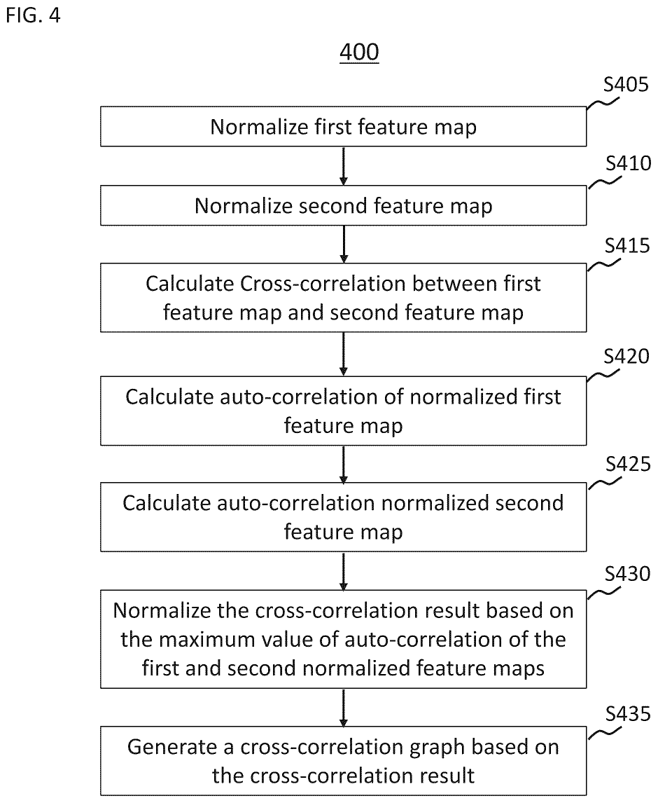

As the details of the normalized cross-correlation result generation process 400 will be described with reference to FIG. 4, the description thereof will be omitted here.

Next, at Step S335, the ranking unit 228 filters a set of target features based on the normalized cross-correlation result to determine a subset of target features that achieve a ranking threshold. In embodiments, the ranking unit may give a higher ranking to those target features that have a higher uniformity level. Accordingly, those target features that have higher uniformity between the first feature map 321 and the second feature map 311, and therefore more accurately represent the conditions of the processing chamber, may be selected for use in state prediction of the semiconductor manufacturing device. In this way, the ranking assigned by the ranking unit indicates the relevance of each target feature with respect to other target features with regard to processing chamber state prediction (e.g., target features with higher uniformity are considered more relevant for assessing the state of a processing chamber).

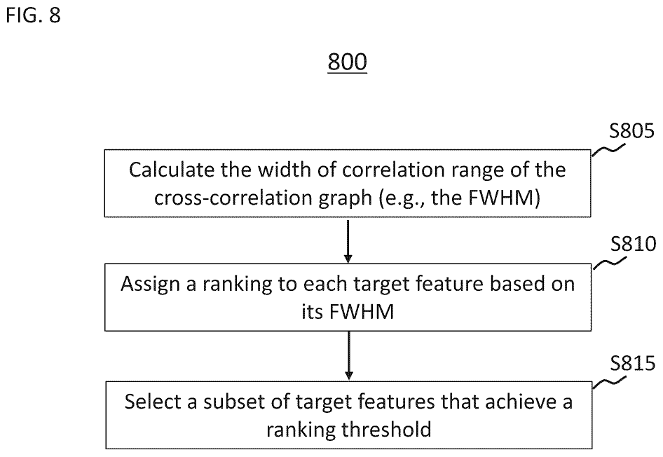

As the details of the target feature ranking process 800 will be described with reference to FIG. 8, the description thereof will be omitted here.

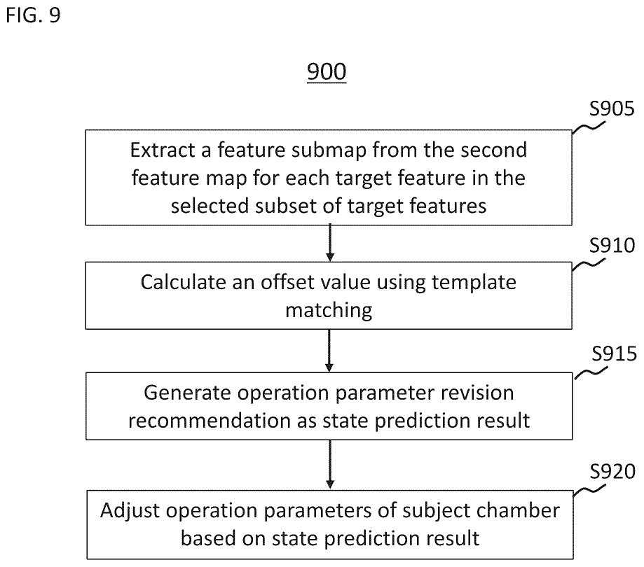

Next, at Step S340, the state prediction unit 230 generates a state prediction result for the subject chamber based on the subset of target features determined in Step S335. In embodiments, this state prediction result may include an operation parameter revision recommendation that indicates changes to a set of operation parameters of the semiconductor manufacturing device that includes the subject chamber to reduce the performance difference of the subject chamber with respect to the reference chamber. As the details of the state prediction result generation process 900 will be described with reference to FIG. 9, the description thereof will be omitted here.

Next, at Step S345, the semiconductor manufacturing device that includes the subject chamber may adjust its operational parameters in accordance with the operation parameter revision recommendation generated in Step S340 to reduce the performance difference of the subject chamber with respect to the reference chamber.

According to the state prediction result generation process 300 described with reference to FIG. 3, it becomes possible to reduce the performance difference (arising from time elapse, component replacement, component cleaning, or the like) of a subject chamber with respect to a reference chamber. In this way, variation in the performance of the semiconductor devices manufactured by semiconductor manufacturing device that includes the subject chamber can be suppressed, and uniform performance of the semiconductor devices can be achieved.

Further, it should be noted that as the state prediction result is generated based on those target features that are determined to have high uniformity (e.g., achieve a ranking threshold) between acceptable chamber states and unacceptable chamber states, noise and irrelevant features can be eliminated, allowing for the generation of a more reliable, accurate state prediction result.

Next, with reference to FIG. 4 to FIG. 7, the normalized cross-correlation result generation process 400 according to the embodiments of the present disclosure will be described. The normalized cross-correlation result generation process 400 is a process for generating a normalized cross-correlation result that indicates a uniformity level of particular target features between different feature maps (e.g., the first feature map 321 and the second feature map 311). The normalized cross-correlation result generation process 400 may be performed by the correlation calculation unit 226 and substantially correspond to Step S330 of the state prediction result generation process 300 illustrated in FIG. 3

First, at Step S405, the correlation calculation unit 226 normalizes the first feature map 321. Here, the correlation calculation unit 226 may normalize the first feature map 321 by calculating an average value of the features included in the first feature map 321, and subtracting this average value from each feature in the first feature map 321. In this way, the first feature map 321 can be normalized to account for different scaling factors or the like between different sensors.

Next, at Step S410, the correlation calculation unit 226 normalizes the second feature map 311. Here, the correlation calculation unit 226 may normalize the second feature map 311 by calculating an average value of the features included in the second feature map 311, and subtracting this average value from each feature in the second feature map 311. In this way, the second feature map 311 can be normalized to account for different scaling factors or the like between different sensors.

Next, at Step S415, the correlation calculation unit 226 calculates the cross-correlation between the normalized first feature map 321 and the normalized second feature map 311. Here, cross-correlation refers to a measure of the similarity between two datasets as a function of the displacement of one dataset relative to the other. For example, given two data sets x and y, the cross correlation between x and y can be calculated using the following Equation 1.

$${\hat{R}}_{xy} ( m ) = \{ \begin{matrix}{\sum }_{n = 0}^{N - m - I} {x}_{n + m} {y}_{n}^{⋆} , & m \geq 0 , \\ {\hat{R}}_{xy}^{⋆} ( - m ) , & m < 0.\end{matrix} \qquad [ Math . 1 ]$$

In the present disclosure, calculating the cross-correlation between the normalized first feature map 321 and the normalized second feature map 311 provides a representation of the similarity between the normalized first feature map 321 and the normalized second feature map 311.

Next, at Step 420, the correlation calculation unit 226 calculates the auto-correlation of the normalized first feature map 321 (e.g., the feature map corresponding to the reference chamber having an acceptable chamber state). Here, auto-correlation refers to a measure of the similarity between a dataset and a delayed copy of itself as a function of the delay. The auto-correlation of the normalized first feature map 321 may be calculated using a conventional technique and is not particularly limited herein.

Next, at Step 425, the correlation calculation unit 226 calculates the auto-correlation of the normalized second feature map 311 (e.g., the feature map corresponding to the subject chamber having an unacceptable chamber state). The auto-correlation of the normalized second feature map 311 may be calculated using a conventional technique and is not particularly limited herein.

Next, at Step S430, the correlation calculation unit 226 normalizes the cross-correlation result generated in Step S415 based on the maximum value of the auto-correlation of the normalized first feature map 321 calculated in Step S420 and the maximum value of the auto-correlation of the normalized second feature map 311 calculated in Step S425. Here, the correlation calculation unit 226 may generate the normalized cross-correlation result using the following Equation 2.

$$Normalized {R}_{( first ) ( second )} = \frac{{R}_{( first ) ( s e c o n d )}}{\sqrt{Rfirst ( 0 ) * R s e c o n d ( 0 )}} \qquad [ Math . 2 ]$$

Here, R_{(first)(second)} refers to the cross-correlation between the normalized first feature map 321 and the normalized second feature map 311 calculated in Step S415, R_{first}(0) refers to the maximum value of the auto-correlation of the normalized first feature map 321 calculated in Step S420, R_{second}(0) refers to the maximum value of the auto-correlation of the normalized second feature map 311 calculated in Step S425, and Normalized R_{(first)(second)} refers to the normalized cross-correlation result.

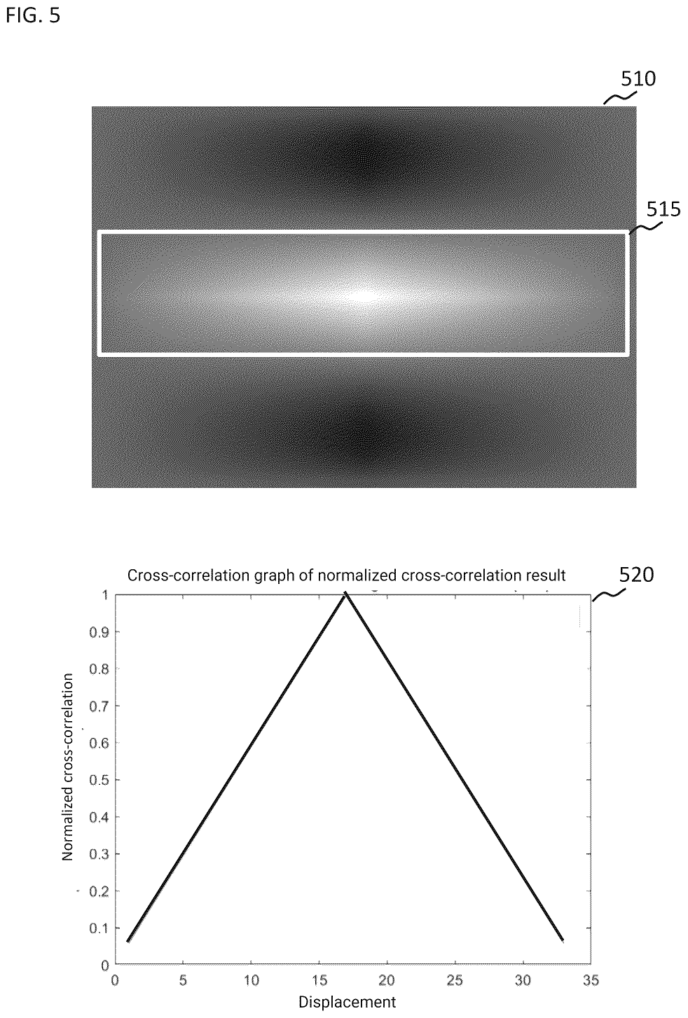

FIG. 5 illustrates an example of a normalized cross-correlation result 510. In embodiments, as illustrated in FIG. 5, the normalized cross-correlation result 510 may be represented as a brightness image, where brighter (e.g., whiter) pixels indicate a greater degree of correlation between the normalized first feature map 321 and the normalized second feature map 311.

Next, at Step S435, the correlation calculation unit 226 may generate a graph based on the normalized cross-correlation result 510 calculated in Step S430. As an example, the correlation calculation unit 226 may extract the data points from the center region 515 of the normalized cross-correlation result 510 illustrated in FIG. 5 and plot them on a graph to generate a cross-correlation graph.

FIG. 5 illustrates an example of a cross-correlation graph 520 generated based on the normalized cross-correlation result 510 calculated in Step S430. As illustrated in FIG. 5, in the cross-correlation graph 520, the vertical axis may represent the degree of correlation between the normalized first feature map 321 and the normalized second feature map 311 and the horizontal axis represents the displacement between the normalized first feature map 321 and the normalized second feature map 311.

In the cross-correlation graph 520 generated based on the normalized cross-correlation result of the normalized first feature map 321 and the normalized second feature map 311, the width of the correlation range (e.g., the full width at half-maximum) represents the uniformity level of a particular target feature between the normalized first feature map 321 and the normalized second feature map 311. As the normalized first feature map 321 was generated based on chamber data for a reference chamber having an acceptable chamber state and the normalized second feature map 311 was generated based on chamber data for a subject chamber having an unacceptable chamber state, the width of the correlation range can be said to represent the uniformity level of a particular target feature between acceptable and unacceptable chamber states.

Aspects of the disclosure relate to the recognition that, as target features that have a high uniformity level between acceptable chamber states and unacceptable chamber states more accurately characterize the conditions of semiconductor manufacturing device processing chambers, ranking target features based on their uniformity and selecting those target features that achieve a ranking threshold (e.g., a high degree of uniformity) allows for the elimination of noise and irrelevant features, and facilitates the generation of more accurate and reliable state prediction results.

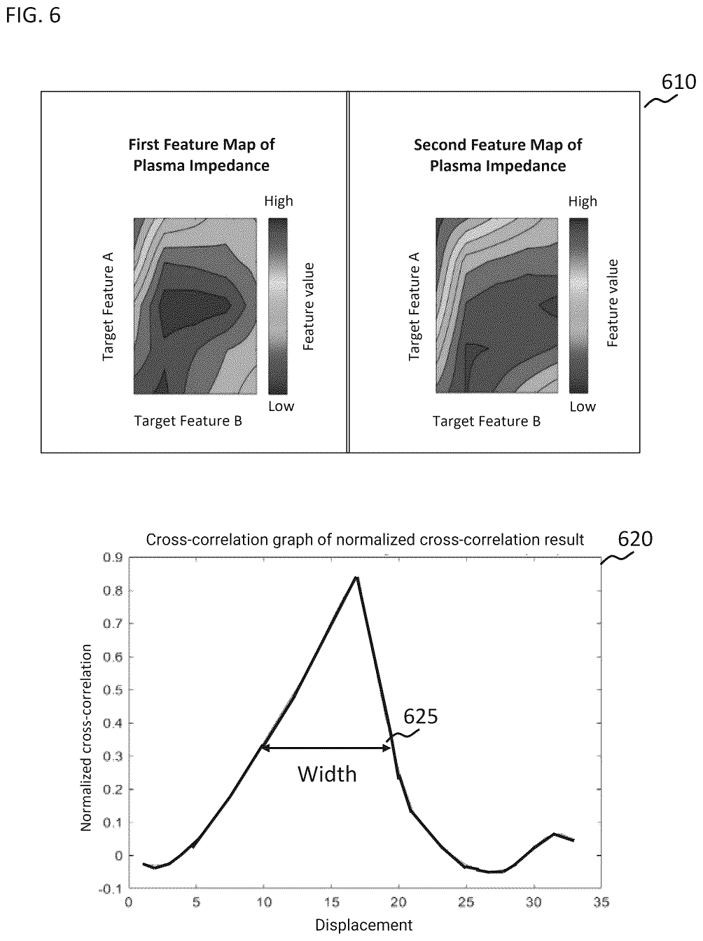

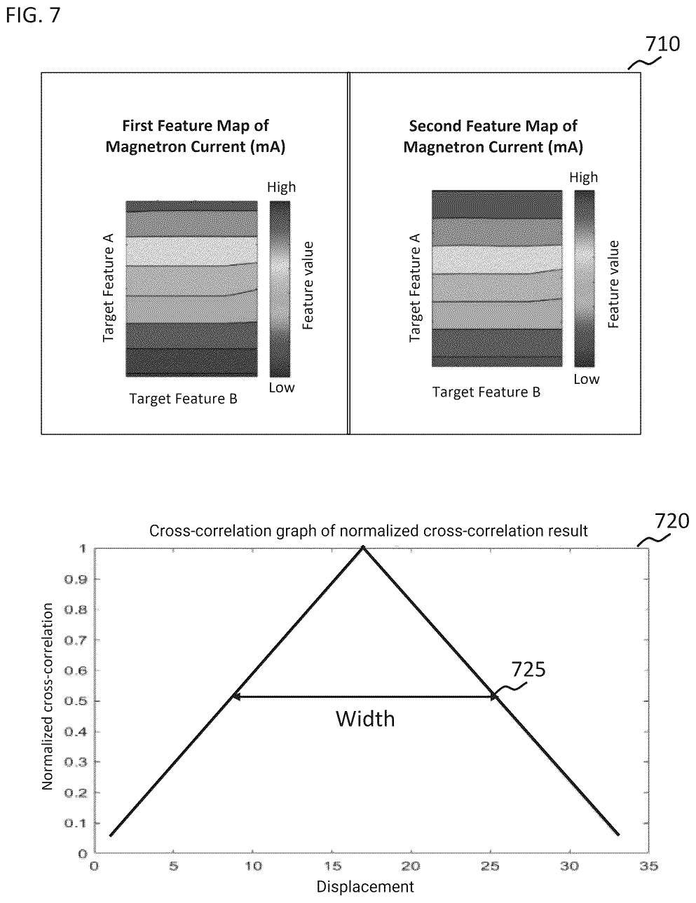

FIG. 6 is a diagram illustrating an example of a cross-correlation graph 620 generated with respect to a set of feature maps 610 corresponding to a target feature of plasma impedance. FIG. 7 is a diagram illustrating an example of a cross-correlation graph 720 generated with respect to a set of feature maps 710 corresponding to a target feature of magnetron current. As described herein, the full width at half-maximum characteristic of the cross-correlation graphs 620, 720 indicates the degree of uniformity of a particular target feature between the respective sets of feature maps 610, 710. As can be seen by comparing the cross-correlation graphs 620 and 720, the full width at half-maximum characteristic 725 of the cross-correlation graph 720 is greater than the full width at half-maximum characteristic 625 of the cross-correlation graph 620. Accordingly, it can be determined that the target feature of magnetron current has a greater uniformity between acceptable and unacceptable chamber conditions than the target feature of plasma impedance.

Next, with reference to FIG. 8, the target feature ranking process according to the embodiments of the present disclosure will be described.

FIG. 8 is a flowchart that illustrates an example flow of the target feature ranking process 800 according to the embodiments of the present disclosure. The target feature ranking process 800 is a process for ranking target features based on their uniformity between feature maps corresponding to acceptable chamber states and unacceptable chamber states. The target feature ranking process 800 may be performed by the ranking unit 228 and substantially correspond to Step S335 of the state prediction result generation process 300 illustrated in FIG. 3.

First, at Step S805, the ranking unit 228 calculates the width of the correlation range of the cross-correlation graph generated in Step S435 of the normalized cross-correlation result generation process 400 described with reference to FIG. 4. Here, the ranking unit 228 may identify the peak correlation value in the cross-correlation graph, identify a point to the left and right of the peak at which the correlation drops to half of its peak value, and measure the distance between these two points as the full width at half-maximum characteristic of the cross-correlation graph.

By repeating the steps of the cross-correlation result generation process 400 and Step S805 for other pairs of feature maps generated for other target features, the width of the correlation range for a plurality of target features can be determined.

Next, at Step S810, the ranking unit 228 assigns a ranking to each target feature of a set of target features (e.g., a plurality of target features for which the full width at half maximum characteristic has been calculated) based on its full width half-maximum value as measured in Step S805, such that target features that have greater width values are assigned higher rankings and target features that have lower width values are assigned lower rankings. In this way, a ranked list in which a set of target features are ranked in order of the width of their correlation values can be obtained. As described herein, target features with greater width values have greater uniformity between acceptable processing chamber states and unacceptable processing chamber states.

Next, at Step S815, the ranking unit 228 selects, from the ranked set of target features obtained in Step S810, a subset of target features that achieve a ranking threshold. Here, the ranking threshold is a criterion, rule, or standard that defines a boundary between target features considered to have high uniformity and target features considered to have low uniformity. In embodiments, the ranking unit 228 may utilize a ranking threshold that specifies a minimum width value, and select all those target features that satisfy the designated minimum width value as the subset of target features. In embodiments, the ranking unit 228 may utilize a ranking threshold that specifies a certain number (e.g., top 20 features) or proportion (e.g., top 10%) of the highest ranking target features, and select a number of the highest ranking target features equal to the specified number or proportion.

According to the target feature ranking process 800 described with reference to FIG. 8, it is possible to rank a set of target features based on their uniformity between acceptable processing chamber states and unacceptable processing chamber states. As described herein, as target features that have a high uniformity level between acceptable chamber states and unacceptable chamber states more accurately characterize the conditions of semiconductor manufacturing device processing chambers, ranking target features based on their uniformity and selecting those target features that achieve a ranking threshold (e.g., a high degree of uniformity) allows for the elimination of noise and irrelevant features and facilitates the generation of more accurate and reliable state prediction results.

Next, with reference to FIG. 9, the state prediction result generation process according to the embodiments of the present disclosure will be described.

FIG. 9 is a flowchart illustrating an example flow of the state prediction result generation process 900 according to the embodiments of the present disclosure. The state prediction result generation process 900 is a process for generating a state prediction result that includes an operation parameter revision recommendation indicating changes to operation parameters of the semiconductor manufacturing device that includes the subject chamber in order to reduce the performance difference of the subject chamber with respect to the reference chamber. The state prediction result generation process 900 may be performed by the state prediction unit 230 of illustrated in FIG. 2.

First, at Step S905, the state prediction unit 230 extracts, as a feature submap, a portion of the second feature map 311 (e.g., the feature map corresponding to the subject chamber having the unacceptable chamber state) for a target feature included in the subset of target features determined in Step S815 of the target feature ranking process 800 described with reference to FIG. 8. For instance, the state prediction unit 230 may extract a 3×3 region from the second feature map 311 as the feature submap.

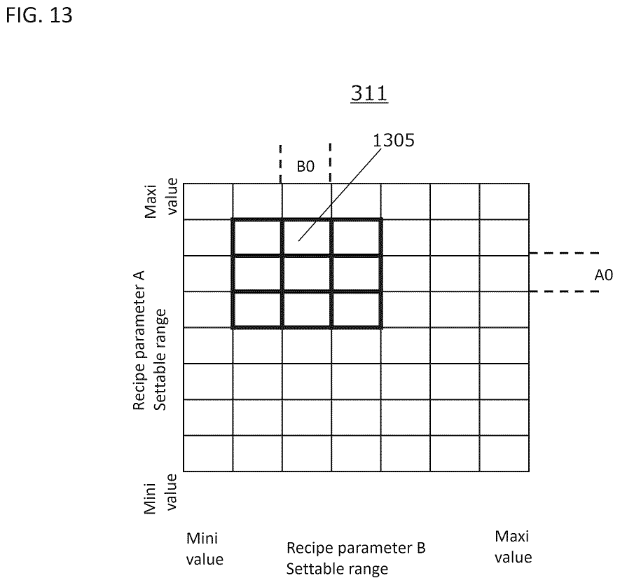

As an example of feature submap extraction will be described with respect to FIG. 13, a description thereof will be omitted here.

Next, at Step S910, the state prediction unit 230 performs a template matching technique using the feature submap extracted from the second feature map 311 in Step S905 and the first feature map 321, and determines the location on the first feature map 321 at which the feature submap most closely matches the first feature map 321. More particularly, the state prediction unit 230 slides the feature submap across the first feature map 321, compares the features of the feature submap with the features of the corresponding region of the first feature map 321, and calculates an offset value indicating the degree of difference between the feature submap and each corresponding region of the first feature map 321. This process may be repeated multiple times for different feature maps corresponding to different target features.

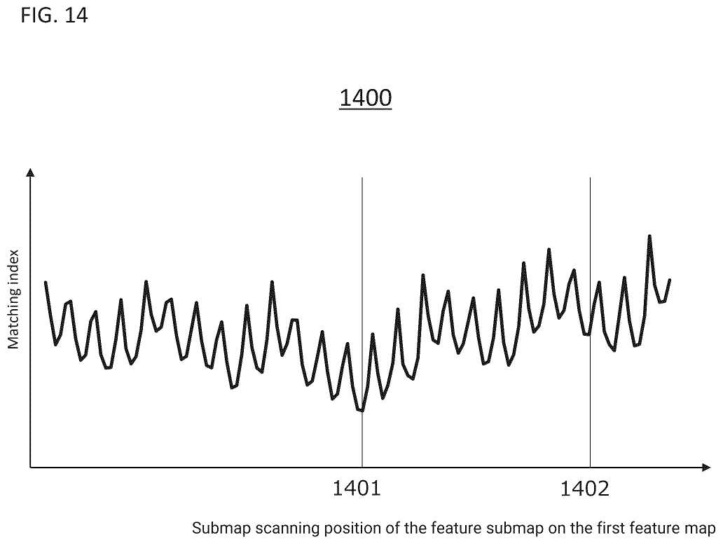

As an example of a template matching result will be described with respect to FIG. 14, a description thereof will be omitted here.

Next, at Step S915, the state prediction unit 230 generates a state prediction result that characterizes a performance difference of the subject chamber with respect to the reference chamber based on the offset value calculated in Step S910. Here, in embodiments, the state prediction unit 230 may generate an operation parameter revision recommendation as the state prediction result. The operation parameter revision recommendation may be information that indicates recommended changes to a set of operation parameters (e.g., operation parameter corresponding to the target features of the processed feature maps) of the semiconductor manufacturing device that includes the subject chamber to reduce the performance difference of the second processing chamber with respect to the reference chamber. As an example, in the case that an offset value is calculated between a feature submap and a first feature map that correspond to a target feature of “magnetron current,” the state prediction unit 230 may generate a state prediction result that indicates an amount by which the magnetron current of the subject chamber should be adjusted to reduce the performance difference between the subject chamber and the reference chamber.

Next, at Step S920, the state prediction unit 230 may transmit a request including the state prediction result to the semiconductor manufacturing device that includes the subject chamber and instruct the semiconductor manufacturing device to adjust its operational parameters in accordance with the operation parameter revision recommendation. Alternatively, in certain embodiments, the state prediction unit 230 may transmit a request including the state prediction result to the user terminal 240 and instruct a user to adjust the operational parameters of the semiconductor manufacturing device that includes the subject chamber in accordance with the operation parameter revision recommendation. In this way, the operational parameters of the semiconductor manufacturing device that includes the subject chamber can be adjusted in order to reduce the performance difference between the subject chamber and the reference chamber.

According to the state prediction result generation process 900 described with reference to FIG. 9, it is possible to reduce the performance difference (arising from time elapse, component replacement, component cleaning, or the like) of a subject chamber with respect to a reference chamber based on an offset value calculated by using a template matching technique with respect to feature maps including target features that have a high uniformity level between acceptable chamber states and unacceptable chamber states. In this way, variation in the performance of the semiconductor devices manufactured by the semiconductor manufacturing device that includes the subject chamber can be suppressed, and uniform performance of the semiconductor devices can be achieved.

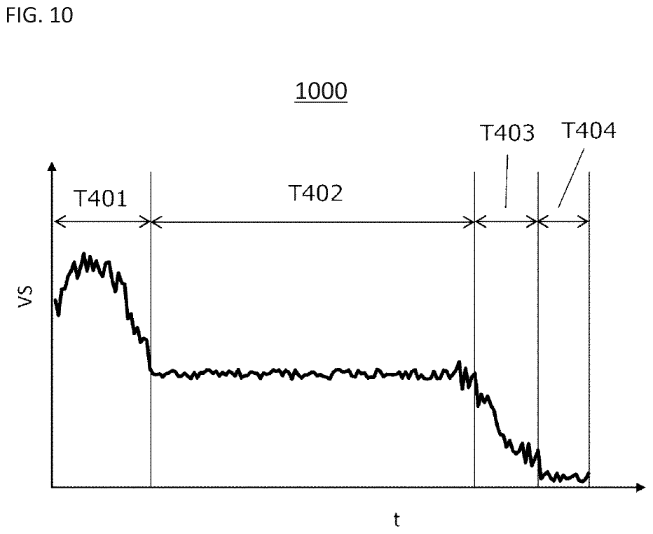

Next, with reference to FIG. 10, an example of a time-series data signal of each sensor value acquired from a semiconductor manufacturing device will be described.

FIG. 10 is a diagram illustrating an example of a time-series data signal 1000 of each sensor value acquired from a semiconductor manufacturing device according to the embodiments of the present disclosure. The time-series data signal 1000 may comprise the reference chamber data 221 or the subject chamber data 211 collected in Steps S310 and S320 of the state prediction result generation process 300 illustrated in FIG. 3.

In FIG. 10, the vertical axis indicates sensor values (VS), and the horizontal axis indicates time (t). Here, the period T401 indicates a transient state area immediately after operational parameter setting, period T402 indicates a steady state area, and periods T403 and T404 indicate areas immediately before the end of plasma processing. As described herein, representative values may be calculated from the time-series data signal 1000 received from each sensor, and features may be calculated from the representative values. Here, the representative value may be statistical data such as an average value or standard deviation in a specific time region of time-series data, or may be a sensor value at a certain time.

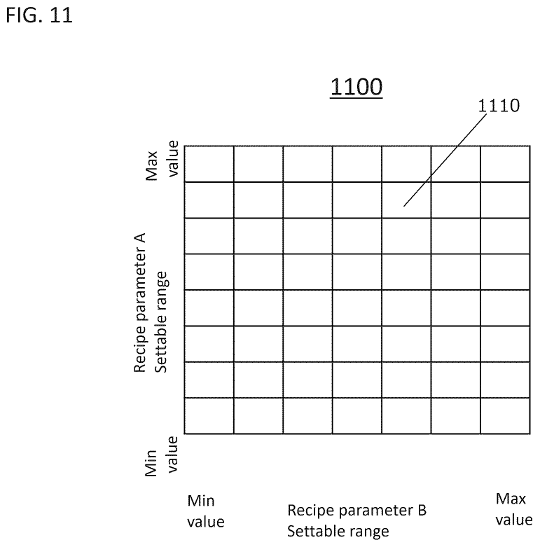

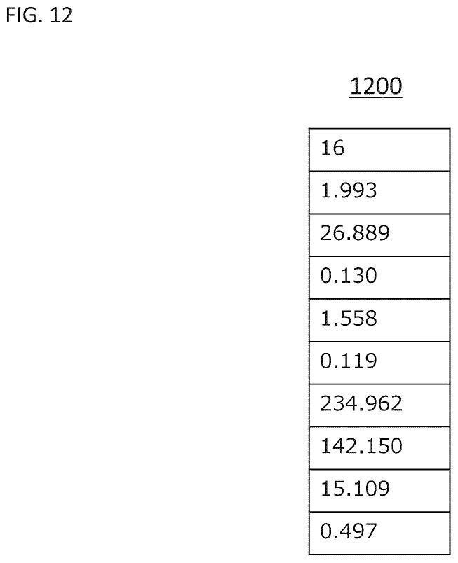

Next, with reference to FIG. 11 and FIG. 12, an example of a feature map data format according to the embodiments of the present disclosure will be described.

FIG. 11 is a diagram illustrating an example of feature map data 1100 according to the embodiments of the present disclosure. The feature map data 1100 illustrates an example of a two-dimensional feature map that may be generated as the first feature map 321 or the second feature map 311 illustrated in FIG. 3. In the feature map data 1100, the height and width direction are associated with value ranges for target features corresponding to different operational parameters of a semiconductor manufacturing unit.

For example, as illustrated in the feature map data 1100 of FIG. 11, the horizontal direction illustrates the range between minimum and maximum values of a target feature B, and the vertical direction illustrates the range between the minimum and maximum values of a target feature A. As described herein, the target features A and B may correspond to adjustable operational parameters of a semiconductor manufacturing unit. For example, the target features A and B may correspond to operational parameters such as microwave intensity, coil current, pressure, or the like, although the target features and associated operational parameters are not limited to these, and other parameters may be used. In the feature map data 1100, each cell 1110 represents a plasma processing condition with the operational parameters defined by target features A and B having certain values.

FIG. 12 illustrates an example of a set of feature values 1200 stored in the feature map data 1100 illustrated in FIG. 11. The set of feature values 1200 represent the values of a particular target feature (e.g., target feature A) that are stored in the cells 1110 of the feature map data 1100 (e.g., a0-a10). For example, each feature value of the set of feature values 1200 may represent values corresponding to operational parameters such as microwave intensity, coil voltage, magnetron current, valve opening degree, pressure, or the like.

As described herein, in Step S315 and S325 of the state prediction result generation process 300 described with reference to FIG. 3, representative values of the sensor values collected during plasma processing may be calculated, and target feature values may be calculated from these representative values and stored in corresponding cells of the feature map data 1100. In certain embodiments, various arithmetic operations may be performed to calculate the target feature values from the representative values. In certain embodiments, the representative values may be normalized using the other feature values stored in the feature map data 1100. In certain embodiments, the representative values may be used directly as the feature values stored in the feature map data 1100.

It should be noted that, although an example of two-dimensional feature map data 1100 and the associated set of feature values 1200 was described with reference to FIG. 12, the present disclosure is not limited thereto, and three-dimensional feature map data may also be used.

Next, with reference to FIG. 13, an example of the feature submap extraction according to the embodiments of the present disclosure will be described.

FIG. 13 is a diagram illustrating an example of the feature submap extraction according to the embodiments of the present disclosure. As described herein, the feature submap is a portion of the feature map that is extracted from the second feature map 311 (e.g., the feature map corresponding to the subject chamber). This feature submap may be compared with the first feature map 321 using a template matching technique to ascertain offset values that indicate a difference in particular target features, and therefore the corresponding operational parameters, between the subject chamber and the reference chamber.

As illustrated in FIG. 13, within the two-dimensional second feature map 311, the region indicated by the bolded line may be extracted as a feature submap 1305. In this way, the feature submap 1305 becomes a 3×3 two-dimensional feature map in which the horizontal axis represents the range of a target feature B and the vertical axis represents the range of a target feature A. Accordingly, each cell of the feature submap 1305 is associated with a two-dimensional target feature set value (e.g., (A0, B0)). As described herein, by performing a template matching process using the feature submap 1305 and the first feature map 321, offset values that indicate the difference in particular target features between the subject chamber and the reference chamber can be determined. It should be noted that, although an example of a two-dimensional feature map was described with reference to FIG. 13, the present disclosure is not limited herein, and the size and dimensionality of the feature map and associated feature submap may be set based on the nature of the application and target features. For instance, 3×3×3 three-dimensional submaps, 1×1×3 one-dimensional submaps, and the like may also be used.

Next, with reference to FIG. 14, an example of template matching result will be described.

FIG. 14 is a diagram illustrating an example of a template matching result 1400 according to the embodiments of the present disclosure. The template matching result 1400 is an example of a result obtained by performing template matching using the first feature map 321 (e.g., the feature map corresponding to the reference chamber that has an acceptable chamber state) and the feature submap 1305 extracted from the second feature map 311 (e.g., the feature map corresponding to the subject chamber that has an unacceptable chamber state).

In FIG. 14, the vertical axis indicates the matching index (MI), and the horizontal axis indicates the submap scanning position (SSP) of the feature submap 1305 on the first feature map 321. As described herein, when the template matching of Step S910 of the state prediction result generation process 900 is performed, the state prediction unit 230 scans the feature submap 1305 extracted in Step S905 on the first feature map 321, and generates the template matching result 1400 by calculating the matching index (MI) at each scanning position (SSP).

In the template matching result 1400 illustrated in FIG. 14, the scanning position 1401 at which the matching index MI is the smallest represents the point where the values of the target features in the feature submap 1305 and the values of the target features in the first feature map 321 are closest to each other (e.g., most similar). The scanning position 1402 represents the scanning position on the first feature map 321 that corresponds to the region on the second feature map 311 from which the feature submap 1305 illustrated in FIG. 13 was extracted. In the case that there is no performance difference between the subject chamber and the reference chamber, the matching index MI should achieve a minimum at the scanning position 1402. Accordingly, the difference between the scanning position 1401 and the scanning position 1402 represents the offset value (e.g., the degree of difference) of the subject chamber with respect to the reference chamber.

In embodiments, this offset value may be calculated based on the difference between the feature values of the feature submap 1305 at scanning position 1401 and scanning position 1402. For instance, when the values of the target features of the center cell of the feature submap 1305 at scanning position 1401 are expressed as (A1), and the values of the target features of the center cell of the feature submap 1305 at scanning position 1402 are expressed as (A0), then the offset value (VA) that characterizes the performance difference of a particular target feature of subject chamber with respect to the reference chamber can be calculated according to the following Equation 3.

$$( VA ) = ( A 0 - A 1 ) \qquad [ Math . 3 ]$$

As described herein, as each target feature corresponds to an adjustable operational parameter of the processing chamber of a semiconductor management device, the offset value (VA) can be used to characterize the difference between the subject chamber and the reference chamber for a particular operational parameter.

Here, the matching index may be calculated using Sum of Absolute Difference (SAD), Sum of Squared Difference (SSD), Normalized Cross Correlation (NCC) Zero-mean Normalized Cross Correlation (ZNCC) or the like. In addition, although an example was described in which the scanning position at which the matching index was lowest was identified as the point at which the feature submap 1305 and the first feature map 321 are most similar, the present invention is not limited herein, and a method of determining the matching point between the feature submap 1305 and the first feature map 321 by performing fitting using a regression model in the vicinity of the minimum value of the matching index may also be used.

After the offset value of one feature submap (for example, feature submap 1305) with respect to the first feature map has been calculated, a new feature submap may be extracted from a different region of the first feature map, and template matching using this new feature submap may be repeated to identify the offset value thereof. In this way, a plurality of offset values for different feature submaps can be calculated. Subsequently, the state prediction unit 230 may generate an aggregate offset value based on each individual offset value result. For instance, the state prediction unit 230 may calculate the average value, the median value, the mode value, a weighted value, or other representative value based on each offset value result as the aggregate offset value. As described herein, this aggregate offset value may be used to generate an operation parameter revision recommendation that indicates the amount that a particular operational parameter (e.g., the operational parameter corresponding to the target feature for which the aggregate offset value was calculated) should be adjusted to reduce the performance difference between the subject chamber and the reference chamber.

As described herein, the performance of semiconductor manufacturing devices (such as plasma processing devices) may change due to aging, component replacement, cleaning, or other factors. Such performance changes may manifest in the performance of the semiconductor devices manufactured by these semiconductor manufacturing devices. It is desirable to reduce the performance differences between plasma processing chambers in order to suppress performance variation in manufactured semiconductor devices.

Aspects of the disclosure relate to the recognition that features that have a high uniformity level between acceptable chamber states and unacceptable chamber states more accurately characterize the conditions of semiconductor manufacturing device processing chambers.

Accordingly, the present disclosure relates to a state prediction technique in which target features are ranked based on their uniformity (as indicated by the width of their correlation range), and using those target features that achieve a ranking threshold (e.g., a high degree of uniformity) to generate a state prediction result. This state prediction result may indicate recommended changes to a set of operation parameters (e.g., operation parameter corresponding to the highly ranked target features) of a subject chamber to reduce the performance difference of the second processing chamber with respect to a reference chamber.

In this way, variation in the performance of the semiconductor devices manufactured by semiconductor manufacturing device that includes the subject chamber can be suppressed, and uniform performance of the semiconductor devices can be achieved. Further, it should be noted that as the state prediction result is generated based on those target features that are determined to have high uniformity between acceptable chamber states and unacceptable chamber states, noise and irrelevant features can be eliminated, allowing for the generation of a more reliable, accurate state prediction result.

The present invention may be a system, a method, and/or a computer program product. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing.

A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While the foregoing is directed to exemplary embodiments, other and further embodiments of the invention may be devised without departing from the basic scope thereof, and the scope thereof is determined by the claims that follow. The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

The terminology used herein is for the purpose of describing particular embodiments only and is not intended to be limiting of the various embodiments. As used herein, the singular forms “a,” “an,” and “the” are intended to include the plural forms as well, unless the context clearly indicates otherwise. “Set of,” “group of,” “bunch of,” etc. are intended to include one or more. It will be further understood that the terms “includes” and/or “including,” when used in this specification, specify the presence of the stated features, integers, steps, operations, elements, and/or components, but do not preclude the presence or addition of one or more other features, integers, steps, operations, elements, components, and/or groups thereof. In the previous detailed description of exemplary embodiments of the various embodiments, reference was made to the accompanying drawings (where like numbers represent like elements), which form a part hereof, and in which is shown by way of illustration specific exemplary embodiments in which the various embodiments may be practiced. These embodiments were described in sufficient detail to enable those skilled in the art to practice the embodiments, but other embodiments may be used and logical, mechanical, electrical, and other changes may be made without departing from the scope of the various embodiments. In the previous description, numerous specific details were set forth to provide a thorough understanding the various embodiments. But, the various embodiments may be practiced without these specific details. In other instances, well-known circuits, structures, and techniques have not been shown in detail in order not to obscure embodiments.

As described herein, aspects of the present disclosure relate to the following aspects.

### (Aspect 1)

A state prediction device for a semiconductor manufacturing device, the state prediction device comprising:
a data acquisition unit configured to:
acquire a first set of operation data for a first processing chamber of a first semiconductor manufacturing device that achieves an operational threshold, and acquire a second set of operation data for a second processing chamber of a second semiconductor manufacturing device that fails to achieve the operational threshold;
a feature management unit configured to:
generate, based on the first set of operation data, a first feature map for a first target feature, and
generate, based on the second set of operation data, a second feature map for the first target feature;
a correlation calculation unit configured to:
calculate a normalized cross-correlation result that indicates a uniformity level of the first target feature between the first feature map and the second feature map;
a ranking unit configured to:
assign, based on the normalized cross-correlation result, a ranking to the first target feature that indicates a relevance of the first target feature with respect to a set of target features with regard to processing chamber state prediction, and
select, from among the set of target features, a subset of target features that achieve a ranking threshold; and
a state prediction unit configured to:
generate, based on the subset of target features, a state prediction result that characterizes a performance difference of the second processing chamber with respect to the first processing chamber.

### (Aspect 2)

The state prediction device according to aspect 1, wherein the correlation calculation unit is configured to:
calculate a cross-correlation result between the first feature map and the second feature map;
calculate a first autocorrelation result for the first feature map;
calculate a second autocorrelation result for the second feature map;
generate the normalized cross-correlation result by normalizing the cross-correlation result based on a first maximum autocorrelation value from the first autocorrelation result and a second maximum autocorrelation value from the second autocorrelation result; and
generate a cross-correlation graph of the normalized cross-correlation result.

### (Aspect 3)

The state prediction device according to aspect 2, wherein the ranking unit is configured to:
identify a full width at half maximum characteristic from the cross-correlation graph; and
assign the ranking to the first target feature based on the full width at half maximum parameter.

### (Aspect 4)

The state prediction device according to any one of aspects 1 to 3, wherein the state prediction unit is configured to:
extract, in a case that the first target feature achieves the ranking threshold, a feature submap from the second feature map;
calculate, using a template matching technique to compare the feature submap extracted from the second feature map with the first feature map, an offset value that indicates a difference in the first target feature between the first processing chamber and the second processing chamber; and
generate, based on the offset value, an operation parameter revision recommendation as the state prediction result that indicates changes to a set of operation parameters of the second semiconductor manufacturing device to reduce the performance difference of the second processing chamber with respect to the first processing chamber.

### (Aspect 5)

The state prediction device according to any one of aspects 1 to 4, wherein the feature management unit is configured to:
calculate a first average value of the first target feature in the first feature map; calculate a second average value of the first target feature in the second feature map;
normalize the first feature map using the first average value; and
normalize the second feature map using the second average value.

### (Aspect 6)

The state prediction device according to any one of aspects 1 to 5, wherein the first semiconductor manufacturing device and the second semiconductor manufacturing device are plasma etching devices.

### REFERENCE SIGNS LIST

200 . . . State prediction system
211 . . . Subject chamber data
220 . . . State prediction device
221 . . . Reference chamber data
222 . . . Data acquisition unit
224 . . . Feature management unit
226 . . . Correlation calculation unit
228 . . . Ranking unit
230 . . . State prediction unit
240 . . . User terminal

1. A state prediction device for a semiconductor manufacturing device, the state prediction device comprising:
a data acquisition unit configured to:
acquire a first set of operation data for a first processing chamber of a first semiconductor manufacturing device that achieves an operational threshold, and
acquire a second set of operation data for a second processing chamber of a second semiconductor manufacturing device that fails to achieve the operational threshold;
a feature management unit configured to:
generate, based on the first set of operation data, a first feature map for a first target feature, and
generate, based on the second set of operation data, a second feature map for the first target feature;
a correlation calculation unit configured to:
calculate a normalized cross-correlation result that indicates a uniformity level of the first target feature between the first feature map and the second feature map;
a ranking unit configured to:
assign, based on the normalized cross-correlation result, a ranking to the first target feature that indicates a relevance of the first target feature with respect to a set of target features with regard to processing chamber state prediction, and
select, from among the set of target features, a subset of target features that achieve a ranking threshold; and
a state prediction unit configured to:
generate, based on the subset of target features, a state prediction result that characterizes a performance difference of the second processing chamber with respect to the first processing chamber.

2. The state prediction device according to claim 1, wherein the correlation calculation unit is configured to:
calculate a cross-correlation result between the first feature map and the second feature map;
calculate a first autocorrelation result for the first feature map;
calculate a second autocorrelation result for the second feature map;
generate the normalized cross-correlation result by normalizing the cross-correlation result based on a first maximum autocorrelation value from the first autocorrelation result and a second maximum autocorrelation value from the second autocorrelation result; and
generate a cross-correlation graph of the normalized cross-correlation result.

3. The state prediction device according to claim 2, wherein the ranking unit is configured to:
identify a full width at half maximum characteristic from the cross-correlation graph; and
assign the ranking to the first target feature based on the full width at half maximum characteristic.

4. The state prediction device according to claim 1, wherein the state prediction unit is configured to:
extract, in a case that the first target feature achieves the ranking threshold, a feature submap from the second feature map;
calculate, using a template matching technique to compare the feature submap extracted from the second feature map with the first feature map, an offset value that indicates a difference in the first target feature between the first processing chamber and the second processing chamber; and
generate, based on the offset value, an operation parameter revision recommendation as the state prediction result that indicates changes to a set of operation parameters of the second semiconductor manufacturing device to reduce the performance difference of the second processing chamber with respect to the first processing chamber.

5. The state prediction device according to claim 1, wherein the feature management unit is configured to:
calculate a first average value of the first target feature in the first feature map;
calculate a second average value of the first target feature in the second feature map;
normalize the first feature map using the first average value; and
normalize the second feature map using the second average value.

6. The state prediction device according to claim 1, wherein the first semiconductor manufacturing device and the second semiconductor manufacturing device are plasma etching devices.

7. A state prediction method for a semiconductor manufacturing device, the state prediction method including:
acquiring a first set of operation data for a first processing chamber of a first semiconductor manufacturing device that achieves an operational threshold;
acquiring a second set of operation data for a second processing chamber of a second semiconductor manufacturing device that fails to achieve the operational threshold;
generating, based on the first set of operation data, a first feature map for a first target feature;
generating, based on the second set of operation data, a second feature map for the first target feature;
calculating a first average value of the first target feature in the first feature map;
calculating a second average value of the first target feature in the second feature map;
normalizing the first feature map using the first average value;
normalizing the second feature map using the second average value;
calculating a cross-correlation result between the first feature map and the second feature map;
calculating a first autocorrelation result for the first feature map;
calculating a second autocorrelation result for the second feature map; and
generating a normalized cross-correlation result that indicates a uniformity level of the first target feature between the first feature map and the second feature map by normalizing the cross-correlation result based on a first maximum autocorrelation value from the first autocorrelation result and a second maximum autocorrelation value from the second autocorrelation result;
generating a correlation graph of the normalized cross-correlation result;
identifying a full width at half maximum parameter from the correlation graph;
assigning, based on the full width at half maximum parameter, a ranking to the first target feature that indicates a relevance of the first target feature with respect to a set of target features with regard to processing chamber state prediction;
selecting, from among the set of target features, a subset of target features that achieve a ranking threshold;
extracting, in a case that the first target feature achieves the ranking threshold, a feature submap from the second feature map;
calculating, using a template matching technique to compare the feature submap extracted from the second feature map with the first feature map, an offset value that indicates a difference in the first target feature between the first processing chamber and the second processing chamber; and
generating, based on the offset value, an operation parameter revision recommendation as a state prediction result that indicates changes to a set of operation parameters of the second semiconductor manufacturing device to reduce a performance difference of the second processing chamber with respect to the first processing chamber.

8. A state prediction system for a semiconductor manufacturing device, the state prediction system comprising:
a semiconductor manufacturing device for manufacturing semiconductor devices;
a state prediction device for generating a state prediction result for the semiconductor manufacturing device; and
a user terminal for managing the semiconductor manufacturing device;
wherein the state prediction device includes:
a data acquisition unit configured to:
acquire a first set of operation data for a first processing chamber that achieves an operational threshold, and
acquire, from the semiconductor manufacturing device, a second set of operation data for a second processing chamber that fails to achieve the operational threshold;
a feature management unit configured to:
generate, based on the first set of operation data, a first feature map for a first target feature, and
generate, based on the second set of operation data, a second feature map for the first target feature;
a correlation calculation unit configured to:
calculate a normalized cross-correlation result that indicates a uniformity level of the first target feature between the first feature map and the second feature map;
a ranking unit configured to:
assign, based on the normalized cross-correlation result, a ranking to the first target feature that indicates a relevance of the first target feature with respect to a set of target features with regard to processing chamber state prediction, and
select, from among the set of target features, a subset of target features that achieve a ranking threshold; and
a state prediction unit configured to:
generate, based on the subset of target features, a state prediction result that characterizes a performance difference of the second processing chamber with respect to the first processing chamber; and
output the state prediction result to the user terminal.
